(19) United States
(12) Patent Application Publication
(10) Pub. No.: US 2025/0219391 A1
(43) Pub. Date: Jul. 3, 2025

(54) LEAKAGE PROTECTION DEVICES, ELECTRICAL CONNECTION EQUIPMENT AND ELECTRICAL APPLIANCES

(71) Applicant: Chengli LI, Suzhou (CN)

(72) Inventors: Chengli LI, Suzhou (CN); Long CHEN, Suzhou (CN)

(73) Assignee: Chengli LI, Suzhou (CN)

(21) Appl. No.: 19/082,731

(22) Filed: Mar. 18, 2025

Related U.S. Application Data
(63) Continuation-in-part of application No. 18/818,335, filed on Aug. 28, 2024.
Application No. 18/818,335 is a continuation-in-part of application No. 18/349,137, filed on Jul. 8, 2023.
Application No. 18/349,137 is a continuation-in-part of application No. 18/169,756, filed on Feb. 15, 2023, now abandoned.

(30) Foreign Application Priority Data
Feb. 13, 2023 (CN) 202310103339.3
Feb. 13, 2023 (CN) 202320192198.2
Mar. 13, 2025 (CN) 202510299856.1
Mar. 13, 2025 (CN) 202520439236.9

(51) Int. Cl. H02H 3/32; H02H 1/00; H02H 3/04

(52) U.S. Cl. CPC H02H 3/32; H02H 1/0007; H02H 1/0061; H02H 3/04

(57) ABSTRACT

A leakage protection device includes: a switch module controlling the power connection between multiple input terminals and multiple output terminals; a leakage detection module, generating a leakage fault signal when a leakage current signal is detected or exceeds a preset threshold; a drive module, driving the switch module to disconnect the power connection between the input and output terminals in response to the leakage fault signal; a relay module, including a switch, coupled between at least one input terminal and the corresponding output terminal; a signal processing and communication module, communicating with a remote control device and controlling the relay module to open or close the switch in response to a control command from the remote control device, thereby disconnecting or connecting the power connection when the switch module is closed. The leakage protection device allows remote control of the leakage protection device safely and reliably.

### BACKGROUND OF THE INVENTION

The invention relates to the electrical field, and in particular to leakage protection devices and related electrical connection devices and electrical appliances.

With the development of society, the number of household appliances has increased and the degree of intelligence of appliances has deepened. There is an increasing demand for leakage protection devices that are both safe and can be remotely monitored and controlled. Many existing leakage protection devices can only simply realize the leakage protection function, but cannot be remotely controlled or remotely monitored. When the user is not near the household appliance, they are unable to monitor the working state of the household appliance, such as whether it is working normally or malfunctioning, and unable to remotely control the power on and off of the household appliance safely and reliably as needed.

### SUMMARY OF THE INVENTION

To solve the above problems, in a first aspect, the present invention provides a leakage protection device, which includes: a plurality of input terminals and a plurality of output terminals; a plurality of current-carrying lines, connecting each input terminal to one or more output terminals; a switch module, coupled between the plurality of input terminals and the plurality of output terminals, configured to control a power connection between the plurality of input terminals and the plurality of output terminals; a leakage detection module, configured to detect a leakage current signal on the plurality of current-carrying lines, and to generate a leakage fault signal when the leakage current signal is detected or when the leakage current signal exceeds a preset threshold; a drive module, coupled to the switch module and the leakage detection module, configured to receive the leakage fault signal and to drive the switch module to disconnect the power connection between the plurality of input terminals and the plurality of output terminals in response to the leakage fault signal; a relay module, including a switch coupled between at least one input terminal and at least one corresponding output terminal; and a signal processing and communication module, coupled to the relay module, configured to wirelessly communicate with a remote control device and to receive a first control command indicating power on or off from the remote control device, and based on the first control command, to control the relay module to open or close the switch, thereby disconnecting or connecting the power connection between at least one input terminal and at least one corresponding output terminal when the switch module is closed.

In some embodiments, the leakage protection device further includes: a state detection module, coupled to at least one of the plurality of output terminals and the signal processing and communication module, and configured to detect the on/off state of the power connection between the at least one output terminal and its corresponding input terminal and to generate a connection state detection signal based thereon; and wherein the signal processing and communication module is further configured to generate a connection state indication signal based on the connection state detection signal and transmit it to the remote control device.

In some embodiments, the state detection module includes a photocoupler and/or a relay.

In some embodiments, the leakage protection device further includes: a parameter acquisition module, coupled between at least one input terminal and at least one corresponding output terminal and coupled to the signal processing and communication module, configured to acquire electrical parameters of the leakage protection device; and wherein the signal processing and communication module is further configured to receive the acquired electrical parameters of the leakage protection device, process the electrical parameters, and transmit the processed electrical parameters to the remote control device.

In some embodiments, the parameter acquisition module includes: a current sensor, configured to collect a current value on at least one of the plurality of current-carrying lines to generate a current sampling signal; and wherein the signal processing and communication module further includes: an operational amplifier, coupled to the current sensor, configured to amplify the current sampling signal; and an analog-to-digital conversion circuit, coupled to the operational amplifier, configured to perform analog-to-digital conversion of the amplified current sampling signal to produce one of the electrical parameters.

In some embodiments, the current sensor includes an alloy resistor and/or a current transformer.

In some embodiments, the parameter acquisition module includes: a rectifier unit configured to rectify an input voltage of at least one of the plurality of input terminals; and wherein the signal processing and communication module further includes: a voltage divider unit coupled to the rectifier unit, configured to divide the rectified input voltage; and an analog-to-digital conversion circuit, coupled to the voltage divider unit, configured to perform analog-to-digital conversion of the divided input voltage to produce one of the electrical parameters.

In some embodiments, the leakage protection device further includes: a switch button, coupled to the signal processing and communication module, configured to, in response to a first operation performed on it, send to the signal processing and communication module a second control command indicating a wireless connection; and wherein the signal processing and communication module is further configured to, in response to the second control command, establish a wireless connection with the remote control device.

In some embodiments, the switch button is configured to, in response to a second operation performed on it, send to the signal processing and communication module a third control command indicating power on or off; and wherein the signal processing and communication module is further configured to, in response to the third control command, control the relay module to open or close the switch, thereby disconnecting or connecting the power connection between the at least one input terminal and the corresponding at least one output terminal when the switch module is closed.

In some embodiments, the leakage protection device further includes: a display module, coupled to the signal processing and communication module, configured to display a network connection state of the signal processing and communication module and/or an on/off state of the power connection between at least one input terminal and the corresponding at least one output terminal.

In some embodiments, the relay module includes a magnetic latching relay.

In some embodiments, the magnetic latching relay has two sets of coils.

In some embodiments, the leakage protection device further includes: a power supply module, coupled to the leakage detection module, the relay module and the signal processing and communication module, configured to supply power to the leakage detection module, the relay module and the signal processing and communication module.

In some embodiments, the leakage protection device further includes: a leakage self-test module, coupled to the leakage detection module and the drive module, configured to periodically generate a simulated leakage current signal to detect whether the leakage detection module has failed, and to generate a self-test fault signal when the leakage detection module has failed; and wherein the drive module is further configured to receive the self-test fault signal, and to drive the switch module to disconnect the power connection between the plurality of input terminals and the plurality of output terminals in response to the self-test fault signal.

The leakage protection device according to the first aspect of the present invention employs a relay module independent of the switch module, and a signal processing and communication module, so that the remote control device can safely and reliably control the power on and off of the leakage protection device. This avoids the occurrence of danger, eliminates potential safety hazards, and increase the safety of the leakage protection device.

In a second aspect, the present invention provides an electrical power connection device, which includes a body and a leakage protection device according to any of the above embodiments, disposed inside the body.

In a third aspect, the present invention provides an electrical appliance, including an electrical load and the above electrical power connection device, coupled between a power supply and the electrical load, configured to supply power to the electrical load.

### BRIEF DESCRIPTION OF DRAWINGS

Preferred embodiments of the present invention are described with reference to the drawings. These drawings explain the embodiments and their operating principle, and only illustrate structures that are necessary to the understanding of the invention. These drawings are not to scale. In the drawings, like features are designated by like reference symbols. In the block diagrams, lines between blocks represent electrical or magnetic coupling of the blocks; the absence of lines between blocks does not mean the lack of coupling.

FIG. 1 is a block diagram of a leakage protection device according to embodiments of the present invention.

FIGS. 2A-2C illustrate a leakage protection device according to an embodiment of the present invention.

FIGS. 3A-3B illustrate a leakage protection device according to another embodiment of the present invention.

FIGS. 4A-4B illustrate a leakage protection device according to yet another embodiment of the present invention.

### DETAILED DESCRIPTION OF THE INVENTION

Preferred embodiments of the present invention are described below with reference to the drawings. These drawings and descriptions explain embodiments of the invention but do not limit the invention. The described embodiments are not all possible embodiments of the present invention. Other embodiments are possible without departing from the spirit and scope of the invention, and the structure and/or logic of the illustrated embodiments may be modified. Thus, it is intended that the scope of the invention is defined by the appended claims.

Before describing the embodiments, some terms used in this disclosure are defined here to help the reader better understand this disclosure.

In this disclosure, terms such as “connect”, “couple”, “link” etc. should be understood broadly, without limitation to physical connection or mechanical connection, but can include electrical connection, and can include direct or indirection connections. Terms such as “a” and “one” do not limit the quantity, and refers to “at least one”.

In the descriptions below, terms such as “including” are intended to be open-ended and mean “including without limitation”, and can include other contents. “Based on” means “at least partly based on.” “An embodiment” means “at least one embodiment.” “Another embodiment” means “at least another embodiment,” etc. In this disclosure, the above terms do not necessarily refer to the same embodiments. Further, the various features, structures, materials or characteristics may be suitably combined in any of the one or more embodiments. Those of ordinary skill in the art may combine the various embodiments and various characteristics of the embodiments described herein when they are not contrary to each other.

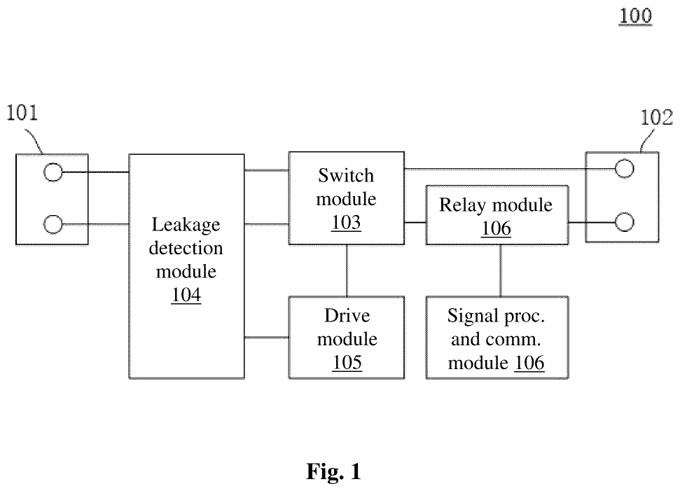

FIG. 1 is a block diagram of a leakage protection device according to embodiments of the present invention. As shown in FIG. 1, the leakage protection device 100 includes input terminals 101, output terminals 102, a switch module 103, a leakage detection module 104, a drive module 105, a relay module 106, and a signal processing and communication module 107. The input terminals 101 and the output terminals 102 are connected through a number of current-carrying lines and connected to the power grid at the input terminals 101. Each input terminal 101 corresponds to one or more output terminals 102. Although two current-carrying lines are shown in FIG. 1, and each current-carrying line connects an input terminal 101 and a corresponding output terminal 102, it can be understood that a set of current-carrying lines can also include more than two current-carrying lines, and/or one input terminal 101 can correspond to more than one output terminal 102. For example, a set of current-carrying lines may include a first current-carrying line connected to the hot line of the power grid and a second current-carrying line connected to the neutral line of the power grid. A separate line may branch from each current-carrying line, so that the leakage protection device 100 has two input terminals 101 and four output terminals 102.

The switch module 103 is coupled between the multiple input terminals 101 and the multiple output terminals 102, and controls the power connection between the input terminals 101 and the output terminals 102. The leakage detection module 104 detects the leakage current signal on the set of current-carrying lines, and generates a leakage fault signal when the leakage current signal is detected or when the leakage current signal exceeds a preset threshold. The drive module 105 is coupled to the switch module 103 and the leakage detection module 104, configured to receive the leakage fault signal, and to drive the switch module 103 to disconnect the power connection between the input terminals 101 and the output terminals 102 in response to the leakage fault signal. The relay module 106 includes a switch, which is coupled between at least one input terminal 101 and at least one corresponding output terminal 102. For example, if one input terminal 101 corresponds to two output terminals 102, then the switch may be coupled between the input terminal 101 and one of the two corresponding output terminals 102. The relay module 106 may include a magnetic latching relay or a conventional relay. The magnetic latching relay may have two sets of coils, which are used to control the opening and closing of the switch. A conventional relay may have a set of coils, which are used to control the switch from open to close, or from close to open. A relay may alternatively include two switches, each switch coupled between an input terminal 101 and a corresponding at least one output terminal 102. The relay module 106 may alternatively include two relays, each relay including a switch, each switch coupled between an input terminal 101 and a corresponding at least one output terminal 102. The signal processing and communication module 107 is coupled to the relay module 106 and wirelessly communicates with a remote control device. The remote control device may be any device with wireless communication function, such as a mobile phone, a laptop computer, a desktop computer, a tablet device, a console, a handheld control device, etc. The wireless communication may include but is not limited to WiFi, Bluetooth, Zigbee, NFC (near-field communication), RFID (radio frequence ID), cellular communication (2G, 3G, 4G, 5G, 6G, etc.), etc. The remote control device may have control software and/or mechanical control switches. The signal processing and communication module 107 may receive a first control command indicating power on or off from a remote control device via wireless communication, and based on the first control command, control the relay module 106 to open or close the switch, thereby disconnecting or connecting the power connection between at least one input terminal 101 and at least one corresponding output terminal 102 coupled to the switch, when the switch module 103 is closed.

The leakage protection device 100 of this embodiment includes a relay module 106 independent of the switch module 103 and a signal processing and communication module 107, so that the remote control device can safely and reliably control the power on and off of the leakage protection device 100, thereby avoiding the occurrence of danger, eliminating potential safety hazards, and increasing the safety of the leakage protection device 100.

In some embodiments, the leakage protection device 100 further includes a state detection module (not shown in FIG. 1), which is coupled to at least one of the output terminals 102 and the signal processing and communication module 107, and configured to detect the on/off state of the power connection between the coupled output terminal 102 and its corresponding input terminal 101 and generates a connection state detection signal accordingly. The state detection module may include a photocoupler and/or a relay. The signal processing and communication module 107 generates a connection state indication signal based on the connection state detection signal, and transmits it to the remote control device. The signal processing and communication module 107 may transmit the connection state indication signal to the remote control device in response to a request from the remote control device, or may actively transmit the connection state indication signal to the remote control device without a request from the latter. In this way, the user can view the on/off state of the power connection of the leakage protection device 100 through the remote control device, so that the user can timely understand the working conditions of the leakage protection device 100 and the electrical appliances connected thereto.

In some embodiments, the leakage protection device 100 further includes a parameter acquisition module (not shown in FIG. 1), which is coupled between at least one input terminal 101 and at least one corresponding output terminal 102 and coupled to the signal processing and communication module 107, and configured to acquire electrical parameters of the leakage protection device 100. The signal processing and communication module 107 receives the acquired electrical parameters of the leakage protection device 100, processes the electrical parameters, and transmits the processed electrical parameters to the remote control device. The electrical parameters may include, for example, input current, input voltage, power, power factor, electric energy, etc. In this way, the user can view the electrical parameters of the leakage protection device 100 through the remote control device, so that the user can timely understand the working conditions of the leakage protection device 100 and the electrical appliances connected thereto.

In some embodiments, the parameter acquisition module includes a current sensor, which collects the current value on at least one current-carrying line in the set of current-carrying lines and generates a current sampling signal. The current sensor may include, for example, an alloy resistor and/or a current transformer. The signal processing and communication module 107 may further include an operational amplifier and an analog-to-digital conversion circuit. The operational amplifier is coupled to the current sensor and amplifies the current sampling signal. The analog-to-digital conversion circuit is coupled to the operational amplifier and performs analog-to-digital conversion on the amplified current sampling signal as one of the electrical parameters.

In some embodiments, the parameter acquisition module includes a rectifier unit that rectifies the input voltage of at least one input terminal 101. The rectifier unit may include, for example, a rectifier diode. The signal processing and communication module 107 may further include a voltage divider unit and an analog-to-digital conversion circuit. The voltage divider unit is coupled to the rectifier unit and divides the rectified input voltage. The analog-to-digital conversion circuit is coupled to the voltage divider unit and performs analog-to-digital conversion on the divided input voltage as one of the electrical parameters.

In some embodiments, the leakage protection device 100 further includes a switch button, which is coupled to the signal processing and communication module 107, and when the first operation is performed on the switch button, it sends a second control command to the signal processing and communication module 107 indicating a wireless connection. The signal processing and communication module 107 establishes a wireless connection with the remote control device in response to the second control command. The first operation of the switch button may be, for example, a long press of the switch button. In this way, the user can realize the wireless connection between the leakage protection device 100 and the remote control device by operating the switch button, which increases the convenience for the user.

In some embodiments, the switch button also sends a third control command to the signal processing and communication module 107 indicating power on and off, when a second operation is performed on the switch button. In response to the third control command, the signal processing and communication module 107 controls the relay module 106 to open or close the switch, and disconnects or connects the power connection between the at least one input terminal 101 and the corresponding at least one output terminal 102 when the switch module 103 is closed. The second operation on the switch button may be, for example, a short press of the switch button. In this way, the user can locally control the on and off of the power connection of the leakage protection device 100 by operating the switch button, which increases the convenience for the user.

In some embodiments, the leakage protection device 100 further includes a display module, which is coupled to the signal processing and communication module 107 and configured to display the network connection state of the signal processing and communication module 107 and/or the on/off state of the power connection between at least one input terminal 101 and the corresponding at least one output terminal 102. In this way, the user can view, through the display device, the network connection state of the signal processing and communication module 107 and/or the on/off state of the power connection of the leakage protection device 100 or one of its output terminals.

In some embodiments, the leakage protection device 100 further includes a power supply module (not shown in FIG. 1), which is coupled to the leakage detection module 104, the relay module 106, and the signal processing and communication module 107, and configured to supply power to these modules. The power supply module rectifies and converts the input voltage at the input end to obtain the power supply voltage required by each module. In this way, no external power supply is required to supply power to the leakage detection module 104, the relay module 106, and the signal processing and communication module 107, thereby increasing the integration and convenience of use of the leakage protection device 100.

In some embodiments, the leakage protection device 100 includes a leakage self-test module (not shown in FIG. 1), which is coupled to the leakage detection module 104 and the drive module 105, and configured to periodically generate a simulated leakage current signal to detect whether the leakage detection module 104 has failed, and to generate a self-test fault signal when the leakage detection module 104 has failed. The drive module 105 receives the self-test fault signal, and drives the switch module 103 to disconnect the power connection between the input terminals 101 and the output terminals 102 in response to the self-test fault signal. In this way, the leakage protection device 100 may perform self-test on the leakage detection module 104, so as to cut off the power connection in time when the leakage detection module 104 has failed, thereby improving the safety and reliability of the leakage protection device 100.

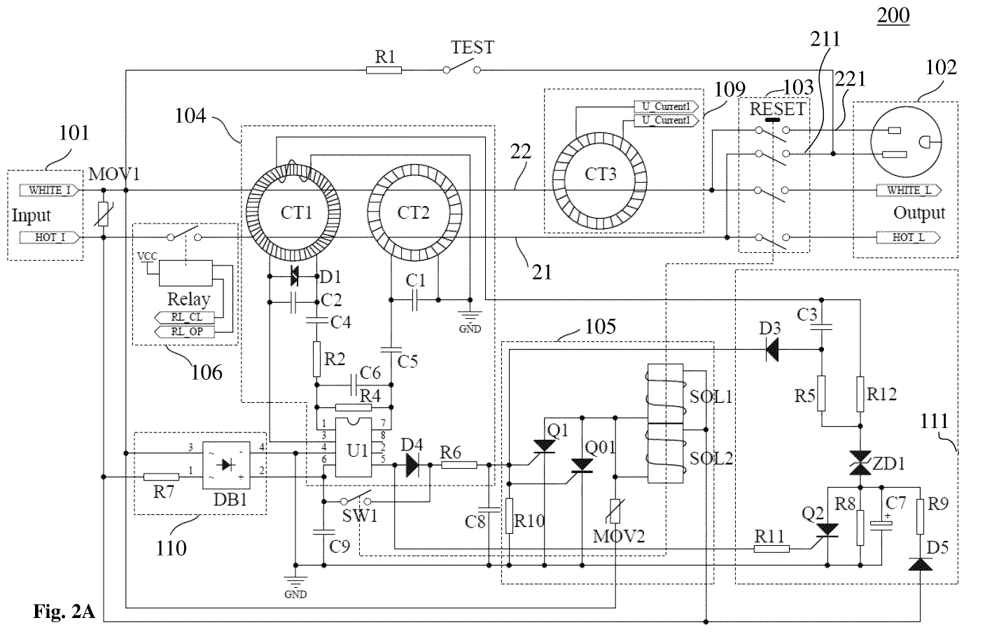

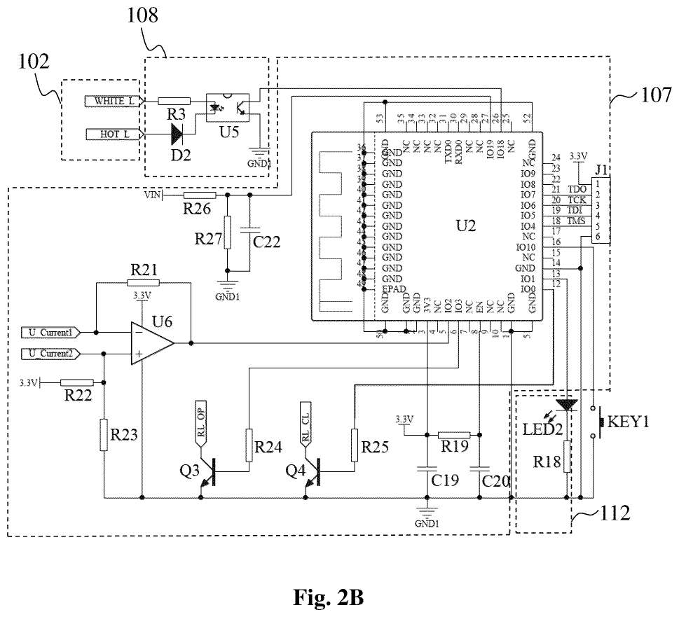

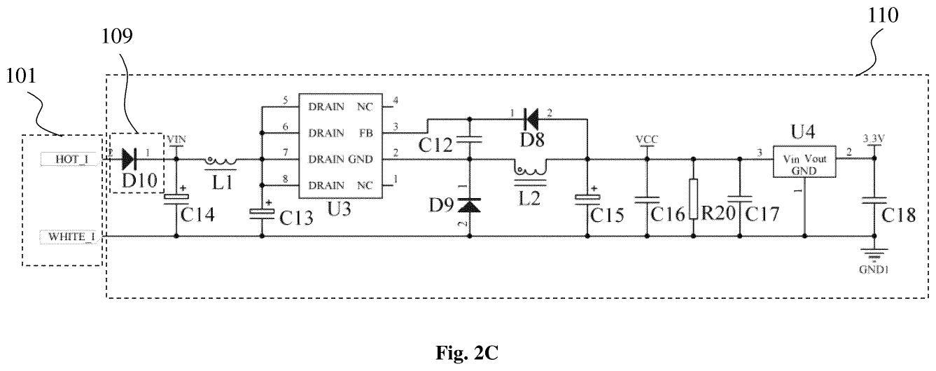

FIGS. 2A-2C illustrate a leakage protection device according to an embodiment of the present invention.

Referring to FIGS. 2A-2C, the leakage protection device 200 includes two input terminals 101 and four output terminals 102, which are connected by a set of current-carrying lines. The set of current-carrying lines includes a first current-carrying line 21, a second current-carrying line 22, and two branches 211 and 221 branched from the first current-carrying line 21 and the second current-carrying line 22, so each input terminal corresponds to two output terminals. The leakage protection device 200 also includes a switch module 103, a leakage detection module 104, a drive module 105, a relay module 106, a signal processing and communication module 107, a state detection module 108, a parameter acquisition module 109, a power supply module 110, a leakage self-test module 111 and a display module 112.

The two input terminals 101 are connected to the power grid. The switch module 103 is coupled between the input terminals 101 and the output terminals 102, and is used to control the power connection between the input terminals 101 and the output terminals 102. The leakage detection module 104 includes a leakage detection ring CT1, a leakage detection chip U1 and its peripheral circuits. The first current-carrying line 21 and the second current-carrying line 22 pass through the leakage detection ring CT1. The drive module 105 includes switch driving elements, namely, solenoids SOL1 and SOL2 and two silicon controlled rectifiers Q1 and Q01. The control electrodes of the silicon controlled rectifiers Q1 and Q01 are connected to the pin 5 of the leakage detection chip U1. In this embodiment, the relay module 106 is a magnetic latching relay, which has two coils and a switch, where the switch is coupled on the first current-carrying line 21, that is, coupled between the input terminal HOT_I and the corresponding output terminal HOT_L. The input ends RL_CL and RL_OP of the two coils are respectively connected to the collectors of transistors Q4 and Q3 in the signal processing and communication module 107. The state detection module 108 includes a resistor R3, a diode D2, and a photocoupler U5 connected to one ends of R3 and D2. The other ends of the resistor R3 and the diode D2 are respectively connected to the output terminal 102, and the other end of the photocoupler U5 is connected to the pin 26 of the signal processing and communication module 107 and the ground. The signal processing and communication module 107 further includes a wireless communication chip U2, an operational amplifier U6, transistors Q3 and Q4, a light-emitting diode LED2, and peripheral circuits. The parameter acquisition module 109 includes a current transformer CT3, through which the second current-carrying line 22 passes, where the current transformer CT3 is connected to the input end of the operational amplifier U6. The wireless communication chip U2 is configured to establish a wireless connection with the remote control device. The parameter acquisition module 109 further includes a rectifier diode D10 connected to the input terminal 101. The power supply module 110 includes a rectifier DB1 connected to the input terminal 101, a rectifier diode D10, an AC/DC chip U3, an LDO (low-dropout regulator) chip U4, and peripheral circuits. The voltage at the input terminal 101 is rectified by the rectifier DB1 and provided to the leakage detection chip U1 to provide a working voltage for it; the rectifier diode D10 produces a rectified voltage VIN, and the AC/DC chip U3 performs analog-to-digital conversion on the rectified voltage to obtain a DC voltage VCC to power the magnetic latching relay 106. The LDO chip U4 processes the DC voltage VCC to generate a 3.3V power supply voltage to power the wireless communication chip U2 and the operational amplifier U6, and at the same time divides the voltage through resistors R22 and R23 to provide a reference voltage for the operational amplifier U6. The leakage self-test module 111 includes a trigger diode ZD1, a capacitor C7, a silicon controlled rectifier Q2 and peripheral components. The control electrode of the silicon controlled rectifier Q2 is connected to the pin 5 of the leakage detection chip U2.

Under normal circumstances, when the RESET button is manually pressed, the switch module 103 is reset, and the power connection between the input terminals 101 and the output terminals 102 is connected. A current flows through HOT_I-R7-DB1 to power the leakage detection chip U1, and generates a stable voltage at the power pin (pin 6) of the leakage detection chip U1. When a leakage current is present on the first current-carrying line 21 and the second current-carrying line 22, the leakage detection ring CT1 detects the leakage current signal, and generates a corresponding induction signal at its secondary end. The leakage detection ring CT1 is coupled to the leakage detection chip U1, and the induction signal is transmitted to the leakage detection chip U1 for processing. When the value of the processed leakage current is greater than the preset threshold, pin 5 of the leakage detection chip U1 outputs a high voltage level (leakage fault signal), otherwise it outputs a low voltage level. The high voltage level of pin 5 of the leakage detection chip U1 is provided to the control electrodes of the silicon controlled rectifiers Q1 and Q01 via the diode D4 and the resistor R6, triggering the silicon controlled rectifiers Q1 and Q01 to turn on. At this time, a current flows into the ground through HOT_I-SOL1/SOL2-Q1/Q01, and the solenoid SOL1/SOL2 generates a large magnetic field, driving the switch module 103 to disconnect the power connection between the input terminals 101 and the output terminals 102.

The leakage protection device 200 also has a leakage self-test function. A current flows through HOT_I-D5-R9 to charge the capacitor C7. As the voltage at the upper end of the capacitor C7 increases, the voltage across the two ends of the trigger diode ZD1 increases accordingly. After a preset period of time, the voltage at the upper end of the capacitor C7 exceeds the trigger voltage of the trigger diode ZD1, the trigger diode ZD1 is turned on, and a current flows through the trigger diode ZD1-R12-CT1-ground to generate a simulated leakage current signal, and a current flows through the resistor R5 to charge the capacitor C3. In the normal working state of the leakage protection device 200, that is, the leakage detection module 104 and the drive module 105 are both working normally, the leakage detection ring CT1 detects the simulated leakage current signal, and its secondary end generates a corresponding induction signal which is transmitted to the leakage detection chip U1. As a result, the pin 5 of the leakage detection chip U1 outputs a high voltage level, and a current flows through the resistor R6 to charge the capacitor C8. At the same time, a current flowing through the resistor R11 triggers the silicon controlled rectifier Q2 to turn on, and the capacitor C7 is quickly discharged through the silicon controlled rectifier Q2, and the voltage at its upper end decreases rapidly. When it drops to a voltage lower than the trigger voltage of the trigger diode ZD1, the trigger diode ZD1 is cut off, and no analog leakage current signal can be generated, and the pin 5 of the leakage detection chip U1 stops outputting a high voltage level. Due to the short trigger time, the lower end voltage of the capacitor C3 and the upper end voltage of capacitor C8 are low at this time, insufficient to trigger the silicon controlled rectifier Q1 and/or Q01 to turn on, and the switch module 103 remains in a closed state. When the leakage detection module 104 has failed, for example, the leakage detection loop CT1 is open or short-circuited, the leakage detection chip U1 is damaged, the resistor R2 is open, etc., and cannot detect the simulated leakage current signal, the pin 5 of the leakage detection chip U1 remains at a low voltage level, and the silicon controlled rectifier Q2 cannot be triggered to turn on. The capacitor C7 cannot be discharged through the silicon controlled rectifier Q2, and the trigger diode ZD1 remains on for a long time, so that the voltage at the lower end of the capacitor C3 continues to rise (i.e., a self-test fault signal is generated) until the silicon controlled rectifier Q1/Q01 is triggered to turn on, and a current flows through the solenoid SOL1/SOL2, generating a large magnetic field to drive the switch module 103 to disconnect the power connection between the input terminals 101 and the output terminals 102.

The leakage protection device 200 also has the function of remotely controlling the power on and off. This function can be realized when the switch module 103 is closed. For example, a remote control application can be provided. After the user installs the remote control application on their mobile phone or computer, they can select the option of disconnecting or connecting the power connection of the leakage protection device 200 in the application. For another example, the user can choose to disconnect or connect the power connection of the leakage protection device 200 through a mechanical button on a handheld control device. When the user needs to control the power on and off of the leakage protection device 200, they select the corresponding option in the application installed on the remote control device or issues the corresponding command through the mechanical button, and the remote control device generates a first control command indicating the power on and off, and transmits it to the signal processing and communication module 107 of the leakage protection device 200 via wireless communication. After receiving the first control command, the signal processing and communication module 107 sends a high level pulse through pin 6 or pin 12 to turn on the transistor Q3 or Q4, thereby controlling the switch of the magnetic latching relay 106 to close or open the switch, thereby connecting or disconnecting the power connection between the input terminal HOT_I and the corresponding output terminal HOT_L, that is, connecting or disconnecting the power connection of the entire leakage protection device 200. When a leakage fault occurs, the switch module 103 disconnects the power connection between the input terminal 101 and the output terminal 102, and the user cannot connect the power connection between the input terminal HOT_I and the corresponding output terminal HOT_L through the remote control device, that is, the power on and off of the leakage protection device 200 cannot be remotely controlled.

Specifically, if the user wishes to disconnect the power connection of the leakage protection device 200, the user sends a first control command to disconnect the power to the signal processing and communication module 107 through the remote control device. After receiving the first control command, the signal processing and communication module 107 sends a high-level pulse through pin 6 of the wireless communication chip U2, so the transistor Q3 is turned on, and the corresponding coil of the magnetic latching relay 106 is energized, generating a magnetic field to drive the switch of the magnetic latching relay 106 to open, thereby disconnecting the power connection between the input terminal HOT_I and the corresponding output terminal HOT_L. If the user wishes to connect the power connection of the leakage protection device 200 again, the user sends a first control command to connect the power to the signal processing and communication module 107 through the remote control device. After receiving the first control command, the signal processing and communication module 107 sends a high-level pulse through pin 12 of the wireless communication chip U2, so the transistor Q4 is turned on, and the corresponding coil of the magnetic holding relay 106 is energized, generating a magnetic field to drive the switch of the magnetic holding relay 106 to close, thereby connecting the power connection between the input terminal HOT_I and the corresponding output terminal HOT_L.

By providing a separate relay module 106 in the leakage protection device 200, the power on and off of the leakage protection device 200 can be controlled independently of the switch module 103, and the power connection of the leakage protection device 200 cannot be connected when the switch module 103 is disconnected, thereby avoiding connecting the power connection in potentially dangerous situations (such as when a leakage fault caused the switch module 103 to open), ensuring that the leakage protection device 200 can be remotely controlled safely and reliably.

It can be understood that for simplicity, only one relay module 106 is provided in the present embodiment, but in other embodiments, two relay modules may be provided, and their switches are respectively coupled to two current-carrying lines, that is, between two input terminals 101 and corresponding output terminals 102. Alternatively, a dual-switch relay may be used, and each switch is respectively coupled between one input terminal and the corresponding output terminal.

The user can further remotely obtain the power connection state of the leakage protection device 200 through the remote control device. As shown in FIG. 2B, one end of the photocoupler U5 is connected to the two output terminals HOT_L and WHITE_L of the leakage protection device 200, and the other end is connected to the pin 26 of the wireless communication chip U2 and the ground. When the input terminals HOT_I and WHITE_I are respectively connected to the output terminals HOT_L and WHITE_L, the photocoupler U5 is turned on, and the voltage at the pin 26 of the wireless communication chip U2 is low (connection state detection signal). When the input terminals HOT_I and WHITE_I are respectively disconnected from the output terminals HOT_L and WHITE_L, the photocoupler U5 is cut off, and the pull-up resistor in the wireless communication chip U2 pulls the voltage at the pin 26 up to a high level. By judging whether the voltage at the pin 26 is low or high, the wireless communication chip U2 can determine the on/off state of the power connection between the input terminals HOT_I and WHITE_I and the output terminals HOT_L and WHITE_L, and generate a connection state indication signal accordingly. The signal processing and communication module 107 may send a connection state indication signal to the remote control device in response to a request from the remote control device or actively (e.g., at a scheduled time or when a connection state changes).

The user can also remotely obtain the electrical parameters of the leakage protection device 200 through the remote control device. The electrical parameters may include but are not limited to input current, input voltage, power, power factor, electric energy, etc. When current flows through the second current-carrying line 22, the current transformer CT3 generates a corresponding current signal, which is transmitted to the operational amplifier U6 of the signal processing and communication module 107, and is amplified by the operational amplifier U6 and transmitted to the pin 5 of the wireless communication chip U2. After the signal is analog-to-digital converted by the built-in analog-to-digital conversion circuit of the wireless communication chip U2, the current magnitude on the second current-carrying line 22 is obtained. On the other hand, the input terminal HOT_I is connected to the rectifier diode D10. After the input voltage is rectified by the rectifier diode D10, it is divided by the voltage divider circuit formed by resistors R26 and R27 in the signal processing and communication module 107. The divided voltage is provided to the pin 27 of the signal processing and communication module 107. After the signal is analog-to-digital converted by the built-in analog-to-digital conversion circuit of the wireless communication chip U2, the value of the input voltage of the input terminal HOT_I is obtained. The signal processing and communication module 107 can also calculate other electrical parameters based on the obtained current and voltage values. The signal processing and communication module 107 can transmit the electrical parameters to the remote control device in response to a request from the remote control device or actively (e.g., at a scheduled time or when the electrical parameters reach certain threshold values).

In addition, the leakage protection device 200 further includes a switch button KEY1 (see FIG. 2B), which is connected to the pin 16 of the wireless communication chip U2. The wireless communication chip U2 may be configured so that different functions can be realized by different operations of the switch button KEY1.

In this embodiment, when the switch button KEY1 is subjected to a first operation (such as a long press), a second control command indicating a wireless connection (such as a WiFi connection) is transmitted to the wireless communication chip U2. In response to the second control command, the wireless communication chip U2 establishes a wireless connection with the remote control device. When the switch button KEY1 is subjected to a second operation (such as a short press), a third control command indicating power on and off is transmitted to the signal processing and communication module 107. In response to the third control command and based on the current state of the switch of the magnetic latching relay 106, the signal processing and communication module 107 sends a high-level pulse through pin 6 or 12 to turn on the transistor Q3 or Q4, so as to control the switch of the magnetic latching relay 106 to close or open the switch, thereby connecting or disconnecting the power connection between the input terminal HOT_I and the corresponding output terminal HOT_L.

When the switch of the magnetic latching relay 106 is currently in a closed state, the second operation performed on the switch button KEY1 causes a third control command indicating disconnection of the power connection to be transmitted to the wireless communication chip U2. In response, pin 6 of the wireless communication chip U2 sends a high-level pulse to turn on the transistor Q3, so that the corresponding coil of the magnetic latching relay 106 is energized, and a magnetic field is generated to drive the switch of the magnetic latching relay 106 to be disconnected, thereby disconnecting the power connection between the input terminal HOT_I and the corresponding output terminal HOT_L. When the switch of the magnetic latching relay 106 is currently in an open state, the second operation performed on the switch button KEY1 causes a third control command indicating connection of the power connection to be transmitted to the wireless communication chip U2. In response, pin 12 of the wireless communication chip U2 sends a high-level pulse to turn on the transistor Q4, so that the corresponding coil of the magnetic latching relay 106 is energized, and a magnetic field is generated to drive the switch of the magnetic latching relay 106 to be closed, thereby connecting the power connection between the input terminal HOT_I and the corresponding output terminal HOT_L. It should be understood that only when the switch module 103 is closed, the power connection between the input terminal HOT_I and the corresponding output terminal HOT_L can be connected by operating the switch key KEY1.

In addition, in this embodiment, the display module 112 includes a light emitting diode LED2, which is connected to the pin 13 of the wireless communication chip U2. The wireless communication chip U2 may be configured to display its network connection state, and/or the on/off state of the power connection between the input end coupled to the switch of the magnetic latching relay 106 and the corresponding output end, through different display modes of the light emitting diode LED2. For example, the light emitting diode LED2 may flash to indicate that the signal processing and communication module 107 is establishing a wireless connection with the remote control device; the light emitting diode LED2 may be steadily on to indicate that the switch of the magnetic latching relay 106 is in a closed state, and the power connection between the input end and the corresponding output end coupled to it is connected; the light emitting diode LED2 may be off to indicate that the switch of the magnetic latching relay 106 is in an open state, and the power connection between the input end and the corresponding output end coupled to it is disconnected.

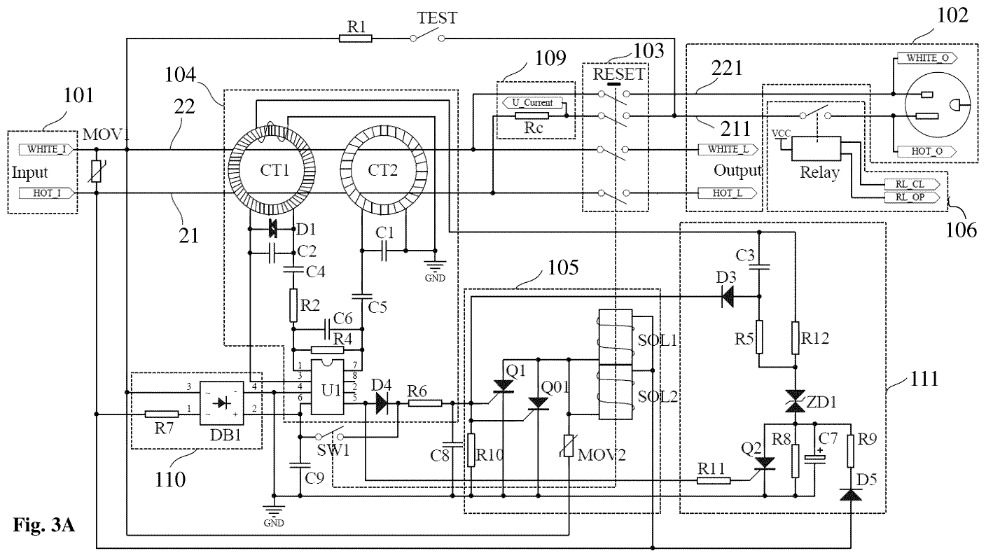

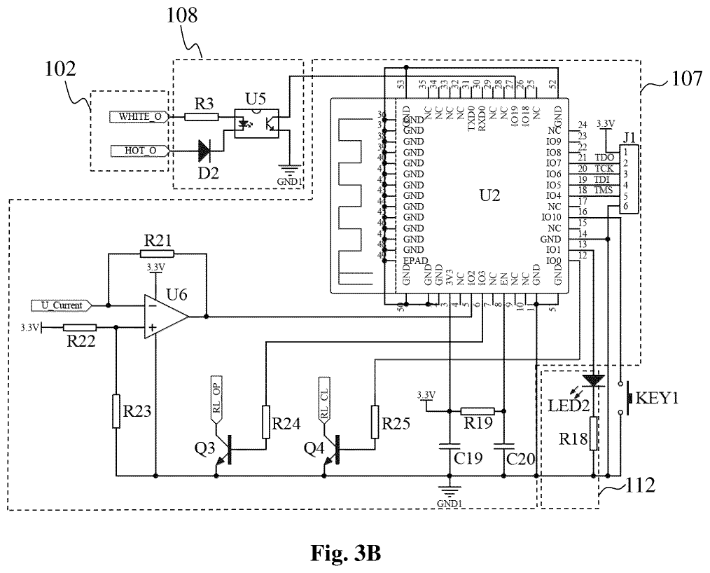

Reference is made to FIGS. 3A-3B. The leakage protection device 300 includes two input terminals 101 and four output terminals, which are connected by a set of current-carrying lines. The set of current-carrying lines also includes a first current-carrying line 21, a second current-carrying line 22, and two branches 211 and 221 branching from the first current-carrying line 21 and the second current-carrying line 22, so that each input terminal corresponds to two output terminals. Different from the embodiment of FIG. 2A, in this embodiment, the switch of the magnetic latching relay 106 is coupled in the branch 211, that is, coupled between the input terminal HOT_I and the corresponding output terminal HOT_O. The power module 110 of the leakage protection device 300 is the same as the leakage protection device 200, so reference may be made to the power module 110 shown in FIG. 2C and its description, which will not be repeated here.

The leakage detection function and the leakage self-test function of the leakage protection device 300 are the same as those of the leakage protection device 200, and are not described in detail here.

The leakage protection device 300 also has the function of remotely controlling the power on and off. This function is also realized when the switch module 103 is closed. Different from the leakage protection device 200, because in the leakage protection device 300, the magnetic latching relay 106 is coupled on the branch line 211, it controls the power on and off between the input terminal HOT_I and the corresponding output terminal HOT_O (i.e., the power connection of the circuit where the branch line 211 is located). For example, a remote control application may be provided; after the user installs the remote control application on their mobile phone or computer, they may select, using the application, the option of disconnecting or connecting the power connection of the circuit where the branch line 211 is located. For another example, the user can choose to disconnect or connect the power connection of the circuit where the branch line 211 is located through a mechanical button on a handheld control device. When the user needs to control the power on and off of the circuit where the branch line 211 is located, they select the corresponding option in the application installed on the remote control device or issue the corresponding command through the mechanical button. The remote control device generates a first control command indicating the power on and off, and transmits it to the signal processing and communication module 107 of the leakage protection device 300 via wireless communication. In response to receiving the first control command, the signal processing and communication module 107 sends a high-level pulse through pin 6 or pin 12 to turn on the transistor Q3 or Q4, so as to control the switch of the magnetic latching relay 106 to close or open the switch, thereby connecting or disconnecting the power connection between the input terminal HOT_I and the corresponding output terminal HOT_O, that is, connecting or disconnecting the power connection of the circuit where the branch line 211 is located. When a leakage fault occurs, the switch module 103 disconnects the power connection between the input terminal 101 and the output terminal 102, and the user is unable to connect or disconnect the power connection between the input terminal HOT_I and the corresponding output terminal HOT_O through the remote control device, that is, unable to remotely control the power on and off of the circuit where the branch line 211 is located.

Specifically, if the user wishes to disconnect the power connection of the circuit where the branch line 211 in the leakage protection device 300 is located, the user sends, through the remote control device, a first control command to disconnect the power to the signal processing and communication module 107. In response to receiving the first control command, the signal processing and communication module 107 sends a high-level pulse through the pin 6 of the wireless communication chip U2, and the transistor Q3 is turned on, so that the corresponding coil of the magnetic latching relay 106 is energized, generating a magnetic field to drive the switch of the magnetic latching relay 106 to be disconnected, thereby disconnecting the power connection between the input terminal HOT_I and the corresponding output terminal HOT_O. If the user wishes to connect the power connection of the circuit where the branch line 211 in the leakage protection device 300 is located again, the user sends, through the remote control device, a first control command to connect the power to the signal processing and communication module 107. In response to receiving the first control command, the signal processing and communication module 107 sends a high-level pulse through pin 12 of the wireless communication chip U2, and the transistor Q4 is turned on, so that the corresponding coil of the magnetic holding relay 106 is energized, generating a magnetic field to drive the switch of the magnetic holding relay 106 to close, thereby connecting the power connection between the input terminal HOT_I and the corresponding output terminal HOT_O.

By providing a separate relay module 106 in the branch line 211 of the leakage protection device 300, the power on and off of the circuit where the branch line 211 in the leakage protection device 300 is located can be controlled independently of the switch module 103; moreover, the power connection of the circuit where the branch line 211 is located cannot be connected when the switch module 103 is disconnected, thereby avoiding the power connection in a potentially dangerous situation (such as a leakage fault causing the switch module 103 to be disconnected), ensuring that the leakage protection device 300 can be remotely controlled safely and reliably.

It should be understood that for simplicity, only one relay module 106 is provided in this embodiment, but in other embodiments, two relay modules may be provided, and their switches are respectively coupled in two branches 211 and 221, that is, between the two input terminals 101 and the corresponding output terminals HOT_O and WHITE_O. Alternatively, a dual-switch relay may be used, each switch being respectively coupled between one input terminal and the corresponding output terminal.

The user can also remotely obtain the power connection state of the leakage protection device 300 through the remote control device. In this embodiment, as shown in FIG. 3B, one end of the photocoupler U5 is connected to the two output terminals HOT_O and WHITE_O of the leakage protection device 300, and the other end is connected to the pin 27 of the wireless communication chip U2 and the ground. When the input terminals HOT_I and WHITE_I are connected to the output terminals HOT_O and WHITE_O, the photocoupler U5 is turned on, and the voltage at the pin 27 of the wireless communication chip U2 is low (connection state detection signal). When the input terminals HOT_I and WHITE_I are disconnected from the output terminals HOT_O and WHITE_O, the photocoupler U5 is cut off, and the pull-up resistor in the wireless communication chip U2 pulls the voltage at the pin 27 up to a high level. By judging whether the voltage at the pin 27 is low or high, the wireless communication chip U2 can determine the on/off state of the power connection between the input terminals HOT_I and WHITE_I and the output terminals HOT_O and WHITE_O, and generate a connection state indication signal accordingly. The signal processing and communication module 107 may send a connection state indication signal to the remote control device in response to a request from the remote control device or actively (e.g., at a scheduled time or when a connection state changes).

The user can also remotely obtain the electrical parameters of the leakage protection device 300 through the remote control device. In this embodiment, the parameter acquisition module 109 includes an alloy resistor, which is connected in series in the branch line 211 and connected to the operational amplifier U6 of the signal processing and communication module 107. The current signal flowing through the alloy resistor is transmitted to the operational amplifier U6, amplified by the operational amplifier U6, and transmitted to the pin 5 of the wireless communication chip U2. An analog-to-digital conversion circuit in the wireless communication chip U2 performs analog-to-digital conversion to generate the current value on the branch line 211. In addition, in this embodiment, there is no need to obtain the input voltage of the input end, so the signal processing and communication module 107 does not include a voltage divider unit. The signal processing and communication module 107 can also calculate other electrical parameters based on the obtained current value. The signal processing and communication module 107 can transmit the electrical parameters to the remote control device in response to a request of the remote control device or actively (e.g. a scheduled time or when the values of the electrical parameter reach certain thresholds).

Similar to the leakage protection device 200, the leakage protection device 300 may also include a switch button KEY1 (see FIG. 3B), which is connected to the pin 16 of the wireless communication chip U2. The wireless communication chip U2 may be configured so that different functions can be achieved by different operations of the switch button KEY1.

In this embodiment, when the switch button KEY1 is subjected to a first operation (such as a long press), a second control command indicating a wireless connection (such as a WiFi connection) is transmitted to the wireless communication chip U2. In response to receiving the second control command, the wireless communication chip U2 establishes a wireless connection with the remote control device. When the switch button KEY1 is subjected to a second operation (such as a short press), a third control command indicating power on and off is transmitted to the signal processing and communication module 107. In response to the third control command and based on the current state of the switch of the magnetic latching relay 106, the signal processing and communication module 107 sends a high-level pulse through pin 6 or 12 to turn on the transistor Q3 or Q4, so as to control the switch of the magnetic latching relay 106 to close or open the switch, thereby connecting or disconnecting the power connection between the input terminal HOT_I and the corresponding output terminal HOT_O.

When the switch of the magnetic latching relay 106 is currently in a closed state, a second operation may be performed on the switch button KEY1 to transmit to the wireless communication chip U2 a third control command indicating disconnection of the power connection. In response, pin 6 of the wireless communication chip U2 sends a high-level pulse to turn on the transistor Q3, so that the corresponding coil of the magnetic latching relay 106 is energized, generating magnetic field to drive the switch of the magnetic latching relay 106 to be disconnected, thereby disconnecting the power connection between the input terminal HOT_I and the corresponding output terminal HOT_O. When the switch of the magnetic latching relay 106 is currently in an open state, a second operation may be performed on the switch button KEY1 to transmit to the wireless communication chip U2 a third control command indicating connection of the power connection. In response, pin 12 of the wireless communication chip U2 sends a high-level pulse to turn on the transistor Q4, so that the corresponding coil of the magnetic latching relay 106 is energized, generating a magnetic field to drive the switch of the magnetic latching relay 106 to be closed, thereby connecting the power connection between the input terminal HOT_I and the corresponding output terminal HOT_O. It should be understood that only when the switch module 103 is closed, the power connection between the input terminal HOT_I and the corresponding output terminal HOT_O can be connected by operating the switch key KEY1.

In addition, the leakage protection device 300 also includes a display module 112. The function of the display module 112 is the same as that of the display module 112 in the leakage protection device 200, and will not be described in detail herein.

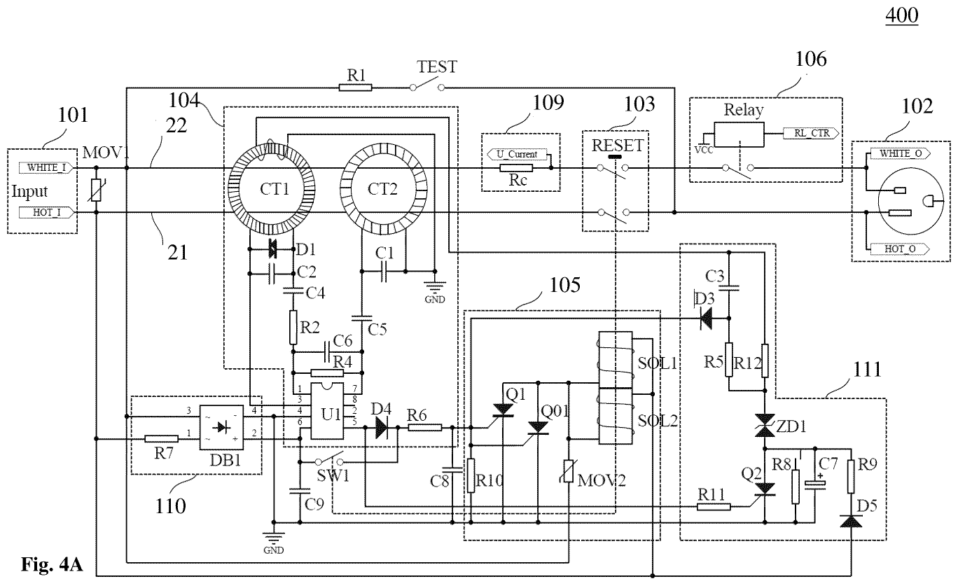

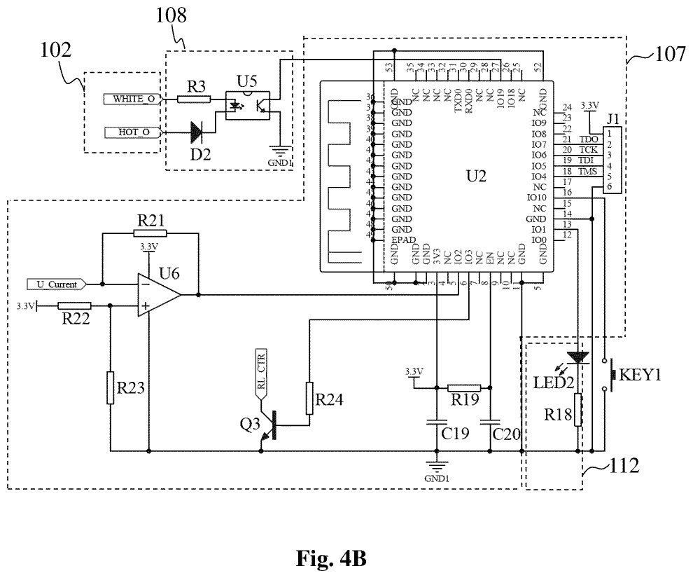

Reference is made to FIGS. 4A-4B. The leakage protection device 400 includes two input terminals 101 and two output terminals 102, which are connected by a set of current-carrying lines. The set of current-carrying lines includes a first current-carrying line 21 and a second current-carrying line 22, and each input terminal corresponds to an output terminal. Different from the embodiment of FIG. 3A, in this embodiment, the relay module 106 includes a conventional relay, whose switch is coupled in the second current-carrying line 22, that is, coupled between the input terminal WHITE_I and the corresponding output terminal WHITE_O. The relay 106 has only one coil, driven by a voltage level driving method, and is connected to the collector of the transistor Q3 of the signal processing and communication module 107. The relay 106 may have a normally open contact or a normally closed contact. The power supply module 110 of the leakage protection device 400 is the same as the leakage protection device 200, so reference can be made to the power supply module 110 shown in FIG. 2C and its description, which will not be repeated here.

The leakage detection function and the leakage self-test function of the leakage protection device 400 are the same as those of the leakage protection devices 200 and 300, and are not described in detail here.

The leakage protection device 400 also has the function of remotely controlling the power on and off. This function is also realized when the switch module 103 is closed. Unlike the leakage protection device 300, because in the leakage protection device 400, the switch of the relay 106 is coupled on the second current-carrying line 22, it controls the on and off of the power connection between the input terminal WHITE_I and the corresponding output terminal WHITE_O. For example, a remote control application may be provided, and after the user installs the remote control application on his mobile phone or computer, they select the option of disconnecting or connecting the power connection of the leakage protection device 400 in the application. For another example, the user can choose to disconnect or connect the power connection of the leakage protection device 400 through a mechanical button on a handheld control device. When the user needs to control the power on and off of the leakage protection device 400, they select the corresponding option in the application installed on the remote control device or issues the corresponding command through the mechanical button, and the remote control device generates a first control command indicating the power on and off, and transmits it to the signal processing and communication module 107 of the leakage protection device 400 via wireless communication. In response to receiving the first control command, the signal processing and communication module 107 sends a high level through the pin 6 to turn on the transistor Q3, so as to control the switch of the relay 106 to close or open the switch, thereby connecting or disconnecting the power connection between the input terminal WHITE_I and the corresponding output terminal WHITE_O, that is, connecting or disconnecting the power connection of the leakage protection device 400. When a leakage fault occurs, the switch module 103 disconnects the power connection between the input terminal 101 and the output terminal 102, and the user is unable to connect or disconnect the power connection between the input terminal WHITE_I and the corresponding output terminal WHITE_O through the remote control device, that is, the power of the leakage protection device 400 cannot be turned on or off.

Specifically, in the case where the relay 106 has a normally open contact, if the user wishes to connect the power connection of the leakage protection device 400, the user sends, through the remote control device, a first control command to connect the power to the signal processing and communication module 107. In response to receiving the first control command, the signal processing and communication module 107 sends a high level through the pin 6 of the wireless communication chip U2 to turn on the transistor Q3, so that the coil of the relay 106 is energized, generating a magnetic field to drive the switch of the relay 106 to close, thereby connecting the power connection between the input terminal WHITE_I and the corresponding output terminal WHITE_O. If the user wishes to disconnect the power connection of the leakage protection device 400 again, the user sends, through the remote control device, a first control command to disconnect the power to the signal processing and communication module 107. In response to receiving the first control command, the signal processing and communication module 107 sends a low level through pin 6 of the wireless communication chip U2 to turn off the transistor Q3, so that the coil of the relay 106 loses power and the switch of the relay 106 is disconnected, thereby disconnecting the power connection between the input terminal WHITE_I and the corresponding output terminal WHITE_O.

In the case where the relay 106 has a normally closed contact, if the user wishes to disconnect the power connection of the leakage protection device 400, the use sends, through the remote control device, a first control command to disconnect the power to the signal processing and communication module 107. In response to receiving the first control command, the signal processing and communication module 107 sends a high level through the pin 6 of the wireless communication chip U2 to turn on the transistor Q3, so that the coil of the relay 106 is energized, generating a magnetic field to drive the switch of the relay 106 to disconnect, thereby disconnecting the power connection between the input terminal WHITE_I and the corresponding output terminal WHITE_O. If the user wishes to connect the power connection of the leakage protection device 400 again, the user sends, through the remote control device, a first control command to connect the power to the signal processing and communication module 107. In response to receiving the first control command, the signal processing and communication module 107 sends a low level through the pin 6 of the wireless communication chip U2 to turn off the transistor Q3, so that the coil of the relay 106 is de-energized, and the switch of the relay 106 is closed, thereby connecting the power connection between the input terminal WHITE_I and the corresponding output terminal WHITE_O.

It should be understood that, for simplicity, only one relay module 106 is provided in the present embodiment, but in other embodiments, two relay modules may be provided, and their switches are respectively coupled in the first current-carrying line 21 and the second current-carrying line 22, that is, between each input terminal and the corresponding output terminal. Alternatively, a dual-switch relay may be used, and each switch is respectively coupled between an input terminal and the corresponding output terminal.

The user can also remotely obtain the power connection state of the leakage protection device 400 through the remote control device. In this embodiment, as shown in FIG. 4B, one end of the photocoupler U5 is connected to the two output terminals HOT_O and WHITE_O of the leakage protection device 400, and the other end is connected to the pin 27 of the wireless communication chip U2 and the ground. When the input terminals HOT_I and WHITE_I are connected to the output terminals HOT_O and WHITE_O, the photocoupler U5 is turned on, and the voltage at the pin 27 of the wireless communication chip U2 is low (connection state detection signal). When the input terminals HOT_I and WHITE_I are disconnected from the output terminals HOT_O and WHITE_O, the photocoupler U5 is cut off, and the pull-up resistor in the wireless communication chip U2 pulls the voltage at the pin 27 up to a high level. By judging whether the voltage at the pin 27 is low or high, the wireless communication chip U2 can determine the on/off state of the power connection between the input terminals HOT_I and WHITE_I and the output terminals HOT_O and WHITE_O, and generate a connection state indication signal accordingly. The signal processing and communication module 107 may send a connection state indication signal to the remote control device in response to a request from the remote control device or actively (e.g., at a scheduled time or when a connection state changes).

The user can also remotely obtain the electrical parameters of the leakage protection device 400 through the remote control device. In this embodiment, the parameter acquisition module 109 includes an alloy resistor, which is connected in series in the second current-carrying line 22 and connected to the operational amplifier U6 of the signal processing and communication module 107. The current signal flowing through the alloy resistor is transmitted to the operational amplifier U6, amplified by the operational amplifier U6, and transmitted to the pin 5 of the wireless communication chip U2. An analog-to-digital conversion circuit in the wireless communication chip U2 converts the signal to digital form to obtain the value of the current on the second current-carrying line 22. In addition, in this embodiment, it is not necessary to obtain the input voltage of the input end, so the signal processing and communication module 107 does not include a voltage divider unit. The signal processing and communication module 107 can also calculate other electrical parameters based on the obtained current value. The signal processing and communication module 107 can send the electrical parameters to the remote control device in response to the request of the remote control device or actively (e.g. a scheduled time or when the electrical parameters reach certain thresholds).

Similar to the leakage protection devices 200 and 300, the leakage protection device 400 also includes a switch button KEY1 (see FIG. 4B), which is connected to the pin 16 of the wireless communication chip U2. The wireless communication chip U2 may be configured so that different operations of the switch button KEY1 by the user can realize different functions.

In this embodiment, when the switch button KEY1 is subjected to a first operation (such as a long press), a second control command indicating a wireless connection (such as a WiFi connection) is transmitted to the wireless communication chip U2. In response to receiving the second control command, the wireless communication chip U2 establishes a wireless connection with the remote control device. When the switch button KEY1 is subjected to a second operation (such as a short press), a third control command indicating power on and off is transmitted to the signal processing and communication module 107. In response to the third control command and based on the current state of the switch of the relay 106, the signal processing and communication module 107 send a high level through pin 6 to turn on the transistor Q3, so as to control the switch of the relay 106 to close or open the switch, thereby connecting or disconnecting the power connection between the input terminal WHITE_I and the corresponding output terminal WHITE_O, that is, connecting or disconnecting the power connection of the leakage protection device 400.

In the case where the relay 106 has a normally open contact, when the switch of the relay 106 is currently in an open state, a second operation may be performed on the switch button KEY1 to send to the wireless communication chip U2 a third control command indicating that the power connection is connected. In response, pin 6 of the wireless communication chip U2 sends a high level to turn on the transistor Q3, so that the coil of the relay 106 is energized, generating a magnetic field to drive the switch of the relay 106 to close, thereby connecting the power connection between the input terminal WHITE_I and the corresponding output terminal WHITE_O. When the switch of the relay 106 is currently in a closed state, a second operation may be performed on the switch button KEY1 to send to the wireless communication chip U2 a third control command indicating that the power connection is disconnected. In response, pin 6 of the wireless communication chip U2 sends a low level to turn off the transistor Q3, so that the coil of the relay 106 loses power, and the switch of the relay 106 is disconnected, thereby disconnecting the power connection between the input terminal WHITE_I and the corresponding output terminal WHITE_O. It should be understood that only when the switch module 103 is closed, the power connection between the input terminal WHITE_I and the corresponding output terminal WHITE_O can be connected by operating the switch key KEY1.

In the case where the relay 106 has a normally closed contact, when the switch of the relay 106 is currently in a closed state, a second operation may be performed on the switch button KEY1 to send to the wireless communication chip U2 a third control command indicating disconnection of the power connection. In response, pin 6 of the wireless communication chip U2 sends a high level to turn on the transistor Q3, so that the coil of the relay 106 is energized, generating a magnetic field to drive the switch of the relay 106 to disconnect, thereby disconnecting the power connection between the input terminal WHITE_I and the corresponding output terminal WHITE_O. When the switch of the relay 106 is currently in an open state, a second operation may be performed on the switch button KEY1 to send to the wireless communication chip U2 a third control command indicating connection of the power connection. In response, pin 6 of the wireless communication chip U2 sends a low level to turn off the transistor Q3, so that the coil of the relay 106 loses power, and the switch of the relay 106 is closed, thereby connecting the power connection between the input terminal WHITE_I and the corresponding output terminal WHITE_O. It should be understood that only when the switch module 103 is closed, the power connection between the input terminal WHITE_I and the corresponding output terminal WHITE_O can be connected by operating the switch key KEY1.

In addition, the leakage protection device 400 also includes a display module 112. The function of the display module 112 is the same as that of the display module 112 in the leakage protection devices 200 and 300, and will not be described in detail herein.

Some additional embodiments of the present invention provide an electrical power connection device, which includes a body and a leakage protection device according to any one of the above embodiments disposed inside the body.

Other additional embodiments of the present invention provide an electrical appliance, which includes an electrical load, and an electrical power connection device coupled between a power supply and the load to supply power to the load, where the electrical power connection device employs a leakage protection device according to any one of the above embodiments.

While the present invention is described above using specific examples, these examples are only illustrative and do not limit the scope of the invention. It will be apparent to those skilled in the art that various modifications, additions and deletions can be made to the leakage protection devices, electrical connection equipment and electrical appliances of the present invention without departing from the spirit or scope of the invention.

1. A leakage protection device, comprising:
a plurality of input terminals and a plurality of output terminals;
a plurality of current-carrying lines, connecting each input terminal to one or more output terminals;
a switch module, coupled between the plurality of input terminals and the plurality of output terminals, configured to control a power connection between the plurality of input terminals and the plurality of output terminals;
a leakage detection module, configured to detect a leakage current signal on the plurality of current-carrying lines, and to generate a leakage fault signal when the leakage current signal is detected or when the leakage current signal exceeds a preset threshold;
a drive module, coupled to the switch module and the leakage detection module, configured to receive the leakage fault signal and to drive the switch module to disconnect the power connection between the plurality of input terminals and the plurality of output terminals in response to the leakage fault signal;
a relay module, including a switch coupled between at least one input terminal and at least one corresponding output terminal; and
a signal processing and communication module, coupled to the relay module, configured to wirelessly communicate with a remote control device and to receive a first control command indicating power on or off from the remote control device, and based on the first control command, to control the relay module to open or close the switch, thereby disconnecting or connecting the power connection between at least one input terminal and at least one corresponding output terminal when the switch module is closed.

2. The leakage protection device of claim 1, further comprising:
a state detection module, coupled to at least one of the plurality of output terminals and the signal processing and communication module, and configured to detect the on/off state of the power connection between the at least one output terminal and its corresponding input terminal and to generate a connection state detection signal based thereon; and
wherein the signal processing and communication module is further configured to generate a connection state indication signal based on the connection state detection signal and transmit it to the remote control device.

3. The leakage protection device of claim 2, wherein the state detection module includes a photocoupler and/or a relay.

4. The leakage protection device of claim 1, further comprising:
a parameter acquisition module, coupled between at least one input terminal and at least one corresponding output terminal and coupled to the signal processing and communication module, configured to acquire electrical parameters of the leakage protection device; and
wherein the signal processing and communication module is further configured to receive the acquired electrical parameters of the leakage protection device, process the electrical parameters, and transmit the processed electrical parameters to the remote control device.

5. The leakage protection device of claim 4, wherein the parameter acquisition module includes:
a current sensor, configured to collect a current value on at least one of the plurality of current-carrying lines to generate a current sampling signal; and
wherein the signal processing and communication module further includes:
an operational amplifier, coupled to the current sensor, configured to amplify the current sampling signal; and
an analog-to-digital conversion circuit, coupled to the operational amplifier, configured to perform analog-to-digital conversion of the amplified current sampling signal to produce one of the electrical parameters.

6. The leakage protection device of claim 5, wherein the current sensor includes an alloy resistor and/or a current transformer.

7. The leakage protection device of claim 4, wherein the parameter acquisition module includes:
a rectifier unit configured to rectify an input voltage of at least one of the plurality of input terminals; and
wherein the signal processing and communication module further includes:
a voltage divider unit coupled to the rectifier unit, configured to divide the rectified input voltage; and
an analog-to-digital conversion circuit, coupled to the voltage divider unit, configured to perform analog-to-digital conversion of the divided input voltage to produce one of the electrical parameters.

8. The leakage protection device of claim 1, further comprising:
a switch button, coupled to the signal processing and communication module, configured to, in response to a first operation performed on it, send to the signal processing and communication module a second control command indicating a wireless connection; and
wherein the signal processing and communication module is further configured to, in response to the second control command, establish a wireless connection with the remote control device.

9. The leakage protection device of claim 8, wherein the switch button is configured to, in response to a second operation performed on it, send to the signal processing and communication module a third control command indicating power on or off; and
wherein the signal processing and communication module is further configured to, in response to the third control command, control the relay module to open or close the switch, thereby disconnecting or connecting the power connection between the at least one input terminal and the corresponding at least one output terminal when the switch module is closed.

10. The leakage protection device of claim 1, further comprising:
a display module, coupled to the signal processing and communication module, configured to display a network connection state of the signal processing and communication module and/or an on/off state of the power connection between at least one input terminal and the corresponding at least one output terminal.

11. The leakage protection device of claim 1, wherein the relay module includes a magnetic latching relay.

12. The leakage protection device of claim 11, wherein the magnetic latching relay has two sets of coils.

13. The leakage protection device of claim 1, further comprising:
a power supply module, coupled to the leakage detection module, the relay module and the signal processing and communication module, configured to supply power to the leakage detection module, the relay module and the signal processing and communication module.

14. The leakage protection device of claim 1, further comprising:
a leakage self-test module, coupled to the leakage detection module and the drive module, configured to periodically generate a simulated leakage current signal to detect whether the leakage detection module has failed, and to generate a self-test fault signal when the leakage detection module has failed; and
wherein the drive module is further configured to receive the self-test fault signal, and to drive the switch module to disconnect the power connection between the plurality of input terminals and the plurality of output terminals in response to the self-test fault signal.

15. An electrical power connection device, comprising:
a body; and
a leakage protection device of claim 1, disposed inside the body.

16. An electrical appliance, comprising:
an electrical load; and
the electrical power connection device of claim 15, coupled between a power supply and the electrical load, configured to supply power to the electrical load.
